(19) United States
(12) Patent Application Publication
(10) Pub. No.: US 2009/0322579 A1
(43) Pub. Date: Dec. 31, 2009

(54) APPARATUS AND METHOD FOR A/D CONVERSION

(75) Inventor: Atsushi MATSUDA, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki (JP)

(21) Appl. No.: 12/434,352

(22) Filed: May 1, 2009

(30) Foreign Application Priority Data
Jun. 25, 2008 (JP) 2008-166153

(51) Int. Cl. H03M 1/34

(52) U.S. Cl. 341/158

(57) ABSTRACT

An A/D conversion apparatus includes an A/D conversion circuit and a reference voltage generating circuit which includes a first switch circuit configured to switch between a state in which the inputs of an operational amplifier are swapped and a state in which these inputs are not swapped, and a second switch circuit configured to switch between a state in which the output voltage of the operational amplifier is output as having a normal phase and a state in which the output voltage is output as having a reversed phase. The A/D conversion circuit obtains a first digital value by setting the first and second switch circuits to a first state, and obtains a second digital value by setting the first and second switch circuits to a second state different from the first state, followed by producing a result of A/D conversion computed from the first and second digital values.

### CROSS-REFERENCE TO RELATED APPLICATIONS

The present application is based upon and claims the benefit of priority from the prior Japanese Patent Application No. 2008-166153 filed on Jun. 25, 2008, with the Japanese Patent Office, the entire contents of which are incorporated herein by reference.

### FIELD

The disclosures herein generally relate to electronic circuits, and particularly relate to an analog-to-digital (A/D) conversion apparatus and A/D conversion method for converting an input analog signal into a digital signal.

### BACKGROUND

A successive approximation A/D converter compares a sampled voltage with a reference voltage, and adjusts the reference voltage in response to the outcome of the comparison, followed by comparing the sampled voltage with the adjusted reference voltage. Such comparison and adjustment are repeated to bring the reference voltage closer to the sampled voltage. The reference voltage is generated according to a digital code. The digital code that is obtained when the reference voltage becomes closest to the sampled voltage is output as the result of A/D conversion. In an A/D converter having such a configuration, a highly accurate base reference voltage may preferably be used to generate a reference voltage responsive to a digital code. Since the circuit elements of any circuits inclusive of semiconductor integrated circuits exhibit temperature-dependent characteristics, a specially designed circuit is used to generate a constant reference voltage that is not affected by temperature changes.

One example of such a reference voltage generating circuit is a band gap reference (BGR) circuit. The BGR circuit uses a combination of an element having a negative temperature dependency and an element having a positive temperature dependency to generate a constant voltage or current that is independent of temperature based on the cancellation of the opposite temperature dependencies. If an element having a negative temperature dependency and an element having a positive temperature dependency are series connected in a straightforward manner, the temperature dependencies of these two elements need to be exact opposite to each other in order to cancel out the temperature dependencies. In semiconductor processes, however, it is difficult to ensure sufficient absolute precision due to process variation. In consideration of this, a mechanism is devised to cancel out temperature dependencies by relying on relative precision between elements.

[Patent Document 1] Japanese Patent Post-Grant Publication No. 6-034359

[Patent Document 2] Japanese Patent Application Publication No. 08-321777

[Patent Document 3] Japanese Patent Application Publication No. 2002-213991

### SUMMARY

According to an aspect of the embodiment, an A/D conversion apparatus includes a reference voltage generating circuit configured to generate a reference voltage, and an A/D conversion circuit configured to convert an input analog voltage into a digital value based on the reference voltage, wherein the reference voltage generating circuit includes a device having a temperature dependency, an operational amplifier configured to receive as an input voltage thereof a voltage output from the device in response to the reference voltage and to produce as an output voltage thereof the reference voltage, a first switch circuit configured to switch between a state in which an inverted input and non-inverted input of the operational amplifier are swapped and a state in which the inverted input and non-inverted input are not swapped, and a second switch circuit configured to switch between a state in which the output voltage of the operational amplifier is output as having a normal phase and a state in which the output voltage of the operational amplifier is output as having a reversed phase, wherein the A/D conversion circuit obtains a first digital value by setting the first switch circuit and the second switch circuit to a first state, and obtains a second digital value by setting the first switch circuit and the second switch circuit to a second state different from the first state, and produces a result of A/D conversion as a value computed from the first digital value and the second digital value.

According to another aspect, a method of performing A/D conversion is provided for an A/D conversion circuit which generates a reference voltage by use of a reference voltage generating circuit, and converts an input analog voltage into a digital value based on the reference voltage. The reference voltage generating circuit includes a device having a temperature dependency, an operational amplifier configured to receive as an input voltage thereof an output voltage of the device responsive to the reference voltage and to produce the reference voltage, a first switch circuit configured to switch between a state in which an inverted input and non-inverted input of the operational amplifier are swapped and a state in which the inverted input and non-inverted input are not swapped, and a second switch circuit configured to switch between a state in which an output voltage of the operational amplifier is output as having a normal phase and a state in which the output voltage of the operational amplifier is output as having a reversed phase. The method includes the steps of obtaining a first digital value by setting the first switch circuit and the second switch circuit to a first state, obtaining a second digital value by setting the first switch circuit and the second switch circuit to a second stage different from the first state, and obtaining a result of A/D conversion as a value computed from the first digital value and the second digital value.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a drawing illustrating an example of the configuration of a band-gap-reference circuit;

FIG. 2 is a drawing illustrating an example of the apparatus configuration that measures temperature by use of an A/D converter;

FIG. 3 is a drawing illustrating temperatures measured in the presence of an offset voltage and temperatures measured in the absence of an offset voltage;

FIG. 4 is a drawing illustrating an example of the configuration of a control circuit;

FIG. 5 is a timing chart illustrating the operation of the control circuit;

FIG. 6 is a flowchart illustrating the operation sequence of a successive approximation register;

FIG. 7 is a drawing illustrating a variation of the configuration of a second switch circuit provided in a BGR circuit;

FIG. 8 is a drawing illustrating a variation of the configuration of the second switch circuit provided in the BGR circuit;

FIG. 9 is a drawing illustrating a variation of the configuration of the second switch circuit provided in the BGR circuit;

FIG. 10 is a drawing illustrating an example of the configuration of a comparator circuit; and

FIG. 11 is a drawing illustrating an example of the system configuration that measures battery voltage by use of an A/D converter.

### DESCRIPTION OF EMBODIMENTS

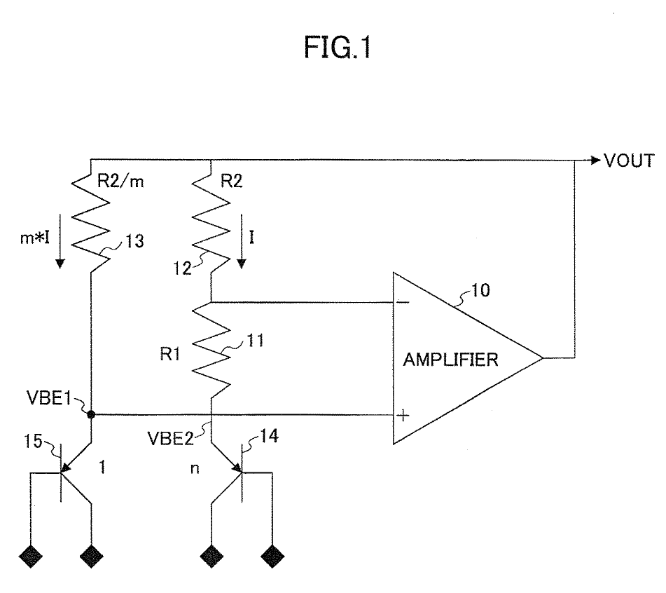

FIG. 1 is a drawing illustrating an example of the configuration of a band-gap-reference circuit. The band-gap-reference circuit includes an amplifier 10, resistors 11 through 13, and PNP transistors 14 and 15. A ratio of the emitter area size of the PNP transistor 15 to the emitter area size of the PNP transistor 14 is 1:n. A ratio of the resistance value of the resistor 13 to the resistance value of the resistor 12 is 1:m. The base and collector of the PNP transistors 14 and 15 are coupled to the ground potential. The base-emitter voltage of the PNP transistor 15 is denoted as VBE1, and the base-emitter voltage of the PNP transistor 14 is denoted as VBE2. Both VBE1 and VBE2 have negative temperature dependency.

Since the amplifier 10 operates to make a potential gap between its inverted input and non-inverted input equal to zero, a voltage drop across the resistor 11 is represented as follows.

ΔVBE=VBE1−VBE2 (1)

When the amount of current flowing through the resistor 12 is I, the amount of current flowing through the resistor 13 becomes equal to mI.

In this case, ΔVBE is represented as follows.

ΔVBE=(kT/q) 1n(mn) (2)

Here, k is Boltzmann constant, T the absolute temperature, q the magnitude of the electron charge, and 1n the natural logarithm. The voltage drop across the resistor 11 having a resistance value R1 is equal to ΔVBE, so that a voltage drop across the resistor 12 having a resistance value R2 becomes equal to ΔVBE×(R2/R1). Accordingly, an output voltage VOUT of the band-gap-reference circuit is represented as follows.

$$\begin{matrix}VOUT = VBE 2 + Δ VBE + Δ VBE \times ( R 2 / R 1 ) \\ = VBE 2 + ( 1 + ( R 2 / R 1 ) ) Δ VBE \\ = VBE 2 + ( 1 + ( R 2 / R 1 ) ) ( kT / q ) ln ( mn )\end{matrix} \qquad ( 3 )$$

VBE2 has a negative temperature dependency, so that its value decreases with a temperature increase. On the other hand, ΔVBE has a positive temperature dependency, so that its value increases with a temperature increase. The value of the factor (1+(R2/R1)) for ΔVBE can thus be properly adjusted to cancel out the negative temperature dependency and the positive temperature dependency, thereby generating the output voltage VOUT that is temperature independent. The above-noted adjustment can be made by ensuring relative resistance value precision without requiring absolute resistance value precision. The cancellation of negative temperature dependency and positive temperature dependency is thus relatively easy.

The band-gap-reference circuit as illustrated in FIG. 1 is used for a Central Processing Unit (CPU) or Application Specific Integrated Circuit (ASIC) that operate according to chip temperature. With some CPUs and ASICs, the power supply voltage may be changed in response to detected temperature in order to provide desired performance, or shutdown is performed when abnormal temperature is detected. As a typical mechanism for temperature detection, a reference voltage may be applied to a series-connected diode and resistor, and the voltage drop across the diode is measured by use of an A/D converter.

Instead of using a dedicated temperature measurement IC, a temperature detection mechanism may be embedded in a CPU or ASIC to achieve cost reduction. The use of the BGR circuit as illustrated in FIG. 1 as an embedded circuit, however, gives rise to a problem in that it is difficult to compensate for the offset voltage of the amplifier 10 from outside the BGR circuit. The offset voltage of an amplifier generally occurs due to manufacturing variation between the characteristics of the input-stage transistor on the inverted-input side and the characteristics of the input-stage transistor on the non-inverted-input side. With the offset voltage being denoted as Vofs, the expression (3) becomes as follows.

VOUT=VBE2+(1+(R2/R1)) (ΔVBE+Vofs)=VBE2+(1+(R2/R1)) ((kT/q) 1n(mn)+Vofs)=Vc+(1+(R2/R1)) Vofs (4)

Here, Vc represents all the components other than the offset-voltage contribution in the output voltage VOUT. In normal designs, 1+(R2/R1) is about 5, for example. In such a case, a voltage that is five times larger than the offset voltage is superimposed on the output voltage VOUT of the BGR circuit. With the offset voltage being 10 mV, for example, the reference voltage generated by the BGR circuit ends up deviating by as much as 50 mV. Such a displacement corresponds to a displacement of approximately 20 degrees Celsius in measured temperature.

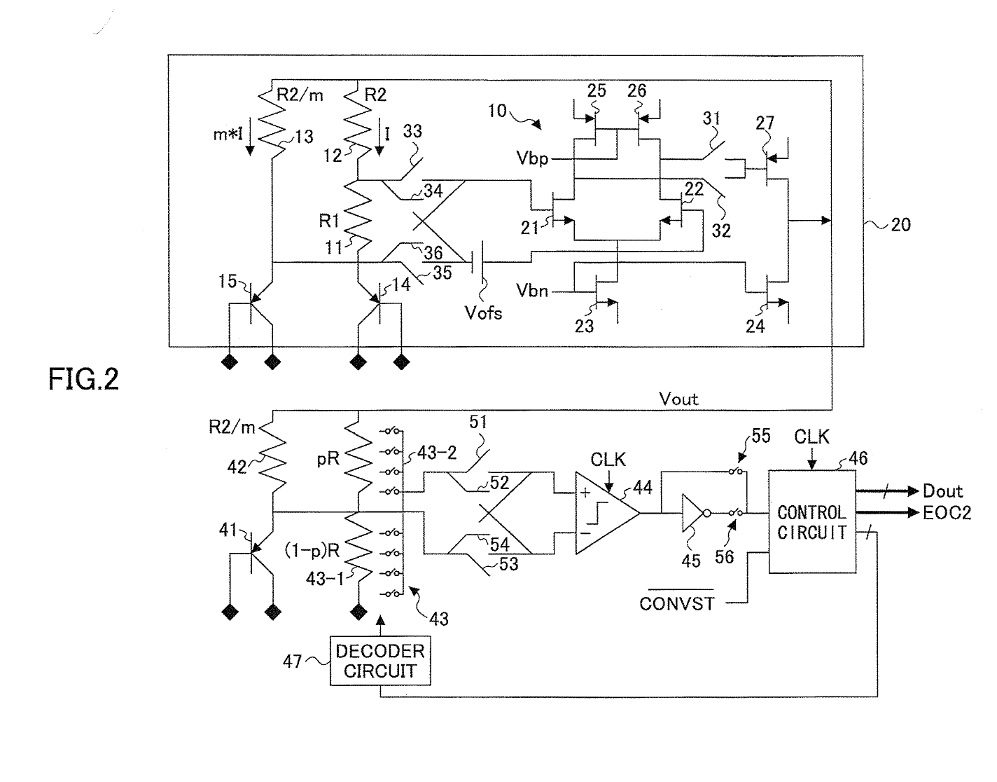

In the following, embodiments of the present invention will be described with reference to the accompanying drawings. FIG. 2 is a drawing illustrating an example of the apparatus configuration that measures temperature by use of an A/D converter. In FIG. 2, the same elements as those of FIG. 1 are referred to by the same numerals, and a description thereof will be omitted.

In the temperature measurement circuit illustrated in FIG. 2, a reference voltage Vout generated by a BGR circuit 20 is applied to a series-connected PNP transistor 41 and resistor 42, and a base-emitter voltage VBE of the PNP transistor 41 is detected by an A/D converter. The base-emitter voltage VBE of the PNP transistor 41 changes according to temperature. A temperature change can thus be detected by measuring the voltage level (hereinafter referred to as Vtemp) of the base-emitter voltage VBE by use of the A/D converter. The A/D converter includes a resistor-based potential divider 43, a comparator circuit 44, a control circuit 46, and a decoder circuit 47. The resistor-based potential divider 43 includes a resistor series 43-1 comprised of series-connected resistors. One end of the resistor series 43-1 receives the reference voltage Vout, and the other end is coupled to the ground potential. In FIG. 2, the resistor series 43-1 is illustrated as being comprised of two resistors for the sake of convenience of illustration. In reality, a larger number of resistors are connected in series to constitute the resistor series 43-1. A switch series 43-2 selects a joint node between two adjacent resistors of the resistor series 43-1, so that the selected joint node is coupled to the comparator circuit 44. Which one of the joint nodes is selected by the switch series 43-2 is controlled by a decode signal supplied from the decoder circuit 47. A joint point that divides the resistor series 43-1 by a ratio of p:1−p may be selected to supply a voltage equal to (1−p)Vout to the comparator circuit 44.

The comparator circuit 44 compares the voltage value (1−p)Vout with the voltage value Vtemp responsive to temperature to supply the result of comparison to the control circuit 46. The control circuit 46 changes a digital code supplied to the decoder circuit 47 in response to which one of (1−p)Vout and Vtemp is greater. The decoder circuit 47 causes the switch series 43-2 to select a joint node in response to the digital code supplied from the control circuit 46. The control circuit 46 successively changes the digital code to be supplied to the decoder circuit 47 in response to which one of (1−p)Vout and Vtemp is greater, thereby gradually bringing (1−p)Vout closer to Vtemp. Specifically, each bit of the digital code supplied to the decoder circuit 47 is successively determined in a descending order from the most significant bit to the least significant bit in response to which one of (1−p)Vout and Vtemp is greater. The value of the digital code whose least significant bit is determined after successive determinations represents the result of A/D conversion, i.e., a digital value into which the analog voltage Vtemp is converted.

In the temperature measurement circuit illustrated in FIG. 2, switch circuits 31 through 36 are provided in the BGR circuit 20 as a mechanism for canceling out an offset voltage Vofs. The BGR circuit 20 includes a PNP transistor 14, a PNP transistor 15, and resistors 11 through 13. An operational amplifier of the BGR circuit 20 receives input voltages made by the above-noted circuit elements in response to the reference voltage Vout to produce the reference voltage Vout as an output voltage. The operational amplifier includes NMOS transistors 21 through 24 and PMOS transistors 25 through 27. The NMOS transistors 21 through 23 and the PMOS transistors 25 and 26 constitute a differential amplifier, and serves as a differential input stage. The NMOS transistor 24 and the PMOS transistor 27 serve as a single-phase output stage that receives an output of the differential input stage.

The switches 33 through 36 together constitute a first switch circuit, which switches between a state in which the inverted input and non-inverted input of the operational amplifier are swapped and a state in which the inverted input and non-inverted input are not swapped. The switches 31 and 32 together constitute a second switch circuit, which switches between a state in which the output voltage of the operational amplifier is output as a normal phase signal and a state in which the output voltage of the operational amplifier is output as a reversed phase signal.

The control circuit 46 of the A/D converter controls each of the above-noted switches. The control circuit 46 obtains a first digital value by setting the first switch circuit and the second switch circuit to respective predetermined states, and obtains a second digital value by setting the first switch circuit and the second switch circuit to respective states that are reverse to the predetermined states. The control circuit 46 obtains a result of A/D conversion as an average of the first digital value and the second digital value. When the first digital value is to be obtained, for example, the first switch circuit is placed in the state in which the inverted input and non-inverted input of the operational amplifier are not swapped. Namely, the switches 33, 34, 35, and 36 are set to ON, OFF, ON, and OFF, respectively. Further, the second switch circuit is placed in the state in which the output voltage is output as having a normal phase. Namely, the switches 31 and 32 are set to ON and OFF, respectively. When the second digital value is to be obtained in such a case, the first switch circuit is placed in the state in which the inverted input and non-inverted input of the operational amplifier are swapped. Namely, the switches 33, 34, 35, and 36 are set to OFF, ON, OFF, and ON, respectively. Further, the second switch circuit is placed in the state in which the output voltage is output as having a reversed phase. Namely, the switches 31 and 32 are set to OFF and ON, respectively.

In this manner, the connections of the switch circuits are set to opposite positions between the case of obtaining the first digital value and the case of obtaining the second digital value, thereby assigning the component of the offset voltage Voft to either a positive direction or a negative direction. In FIG. 2, the offset voltage Voft is illustrated as a power supply unit that is inserted into the circuit to generate the voltage level Voft. In reality, the offset voltage Voft is attributable to asymmetry between the two inputs of the operational amplifier caused by manufacturing variation and the like. The contribution of this offset voltage Voft is alternately assigned in a positive direction and in a negative direction to obtain the respective digital values, which are then averaged to produce a correct A/D conversion value by canceling out the effect of the offset voltage.

In FIG. 2, the resistance value of the resistor 42 is equal to the resistance value of the resistor 13, i.e., equal to R2/m. Further, the PNP transistor 41 and the PNP transistor 15 have the same characteristics. In such a case, the voltage Vtemp is represented as follows, similarly to the expression (4) previously described.

$$\begin{matrix}Vout - Vtemp = \\ = ( R 2 / R 1 ) ( kT / q ) ln ( mn ) + ( R 2 / R 1 ) Vofs\end{matrix}$$

With a ratio of resistor division being denoted as p, a divided voltage Vdiv that is to be subjected to comparison is represented as follows.

Vout−Vdiv=p(Vc+(1+(R2/R1)) Vofs)

With p1 denoting the resistor division ratio that is observed when Vtemp is equal to Vdiv, temperature T is obtained as follows.

T=A (p1vc+(p1(1+(R2/R1))−(R2/R1))Vofs)

Here, A is equal to (q/k)/((R2/R1) 1n(mn)). A resistor division ratio p2 may then be obtained upon measuring temperature T again by placing the switch circuits in the reversed states. In such a case, the following relationship is satisfied.

T=A (p2Vc−(p2(1+(R2/R1))−(R2/R1))Vofs)

In the above calculation, the contribution of the offset voltage Voft is regarded as being positive in the case of p1, and is regarded as being negative in the case of p2. An average Tav of the two measured temperatures T is represented as follows.

Tav=Avc (p1+p2)/2+AVofs(p1−p2)(1+(R2/R1))/2

If (p1−p2)/2 is substantially smaller than (p1+p2)/2, the offset voltage can properly be ignored. That is, correct temperature can be obtained by calculating an average of T1 and T2.

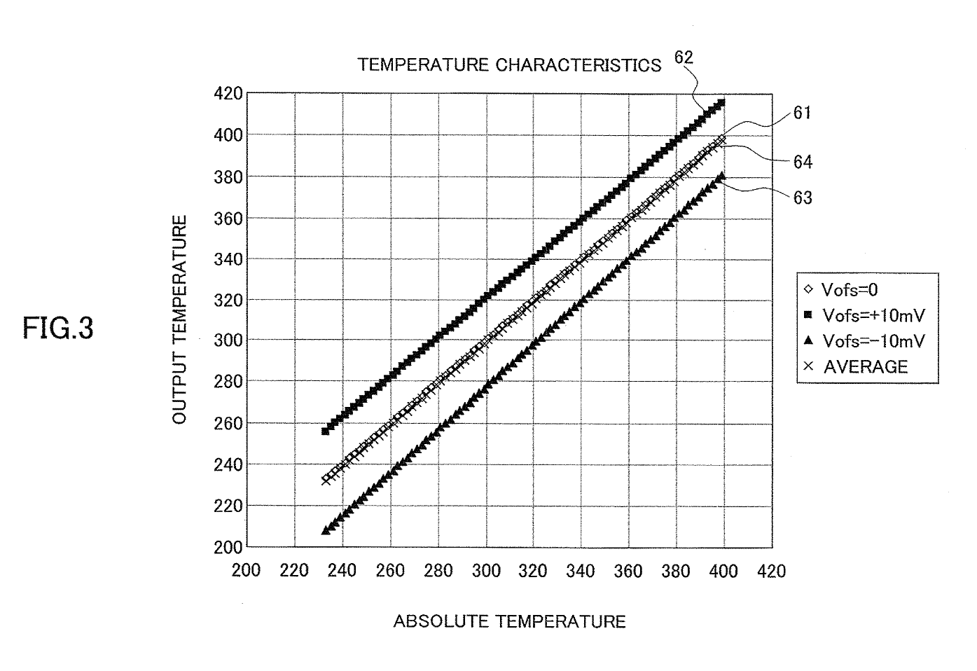

FIG. 3 is a drawing illustrating temperatures measured in the presence of an offset voltage and temperatures measured in the absence of an offset voltage. In FIG. 3, the horizontal axis represents true absolute temperature, and the vertical axis represents measured absolute temperature. A temperature line 61 plotted by use of rhombus marks represents measured temperatures in the case of the offset voltage being zero. In this case, measured temperatures are equal to true temperatures. A temperature line 62 plotted by use of square marks represents measured temperatures in the case of the offset voltage being +10 mV. In this case, measured temperatures differ from true temperatures by a margin of approximately 20 degrees Celsius. A temperature line 63 plotted by use of triangle marks represents measured temperatures in the case of the offset voltage being −10 mV. In this case, measured temperatures differ from true temperatures by a margin of approximately 20 degrees Celsius. A temperature line 64 plotted by use of “x” marks represents average temperatures between the measured temperatures obtained in the case of the offset voltage being +10 mV and the measured temperatures obtained in the case of the offset voltage being −10 mV. In this case, measured temperatures are substantially equal to true temperatures. In the temperature measurement circuit illustrated in FIG. 2, the switching function of the switch circuits serves to cause the offset voltage Voft to contribute alternately in a positive direction and in a negative direction for temperature measurement. In the example illustrated in FIG. 3, the measured temperatures in the case of the offset voltage being +10 mV and the measured temperatures in the case of the offset voltage being −10 mv are alternately obtained. Two measured temperatures obtained in this manner (or two digital code values) are added together to produce their average value. A correct measured temperature (or correct digital value) can thus be obtained.

In the circuit illustrated in FIG. 2, switch circuits 51 through 56 are provided in the A/D converter as a mechanism for canceling out an offset of the comparator circuit 44 similarly to the manner in which the offset voltage Vofs of the operational amplifier is cancelled out in the BGR circuit 20. The resistor-based potential divider 43 generates a comparison-purpose voltage (i.e., Vdiv) by dividing the reference voltage Vout in response to a digital code. A third switch circuit including the switches 51 through 54 is provided on the input side of the comparator circuit 44, which receives the comparison-purpose voltage Vdiv and the input analog voltage Vtemp as its two inputs. The third switch circuit is operable to switch between a state in which the two inputs of the comparator circuit 44 are swapped and a state in which these two inputs are not swapped. On the output side of the comparator circuit 44, a fourth switch circuit including the switches 55 and 56 and an inverter 45 is provided. The fourth switch circuit is operable to switch between a state in which the output of the comparator circuit 44 is logically inverted and a state in which the output is not logically inverted. The control circuit 46 is coupled to the comparator circuit 44 via the fourth switch circuit. The control circuit 46 generates a digital code in response to a selected one of the logically inverted comparison result and the logically non-inverted comparison result supplied via the fourth switch circuit from the comparator circuit 44.

In the above-described configuration, the third switch circuit and the fourth switch circuit are set to respective predetermined states at the time of obtaining a first digital value, and are set to respective states that are reverse to these predetermined states at the time of obtaining a second digital value. When the first digital value is to be obtained, for example, the third switch circuit is placed in the state in which the two inputs of the comparator circuit 44 are not swapped. Namely, the switches 51, 52, 53, and 54 are set to ON, OFF, ON, and OFF, respectively. Further, the fourth switch circuit is placed in the state in which the output of the comparator circuit 44 is not logically inverted, for example. Namely, the switches 55 and 56 are set to ON and OFF, respectively. When the second digital value is to be obtained in this case, the third switch circuit is placed in the state in which the two inputs of the comparator circuit 44 are swapped. Namely, the switches 51, 52, 53, and 54 are set to OFF, ON, OFF, and ON, respectively. Further, the fourth switch circuit is placed in the state in which the output of the comparator circuit 44 is logically inverted. Namely, the switches 55 and 56 are set to OFF and ON, respectively.

In this manner, the connections of the switch circuits are set to opposite positions between the case of obtaining the first digital value and the case of obtaining the second digital value, thereby assigning the component of the offset voltage of the comparator circuit 44 to either a positive direction or a negative direction. As previously described, the control circuit 46 obtains an average value of the first digital value and the second digital value. Through such averaging, the offset voltage of the comparator circuit 44 is also cancelled out. Namely, averaging of the first digital value and the second digital value simultaneously cancels out both the offset voltage Voft of the operational amplifier of the BGR circuit 20 and the offset voltage of the comparator circuit 44. In other words, a single averaging operation can simultaneously remove the effect of two offset voltages.

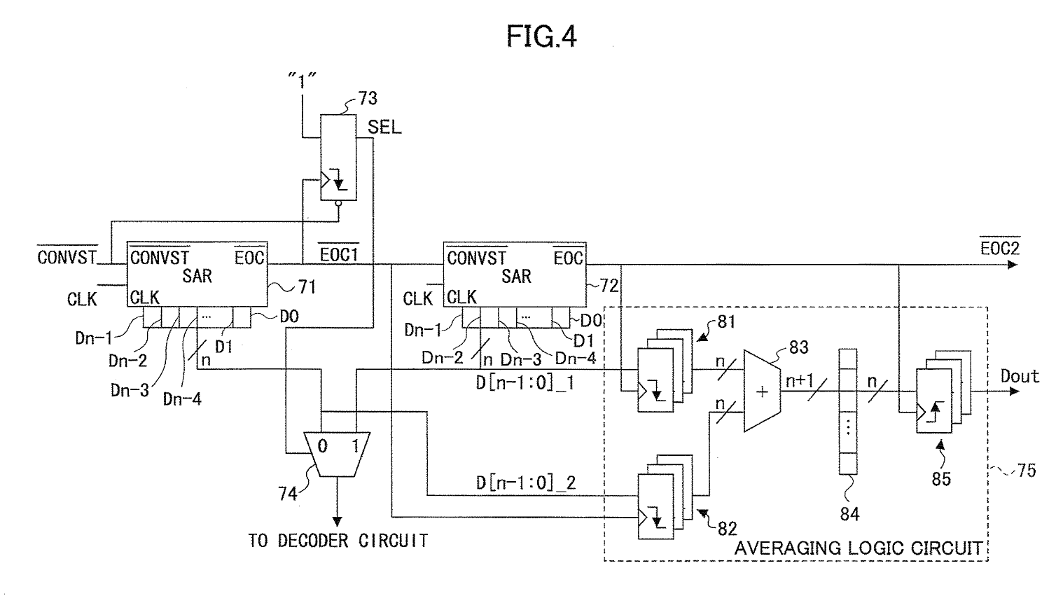

FIG. 4 is a drawing illustrating an example of the configuration of the control circuit 46. The control circuit 46 illustrated in FIG. 4 includes successive approximation registers (SAR) 71 and 72, a flip-flop 73, a selector 74, and an averaging logic circuit 75. The averaging logic circuit 75 includes a register 81, a register 82, an adder circuit 83, a latch circuit 84, and a register 85.

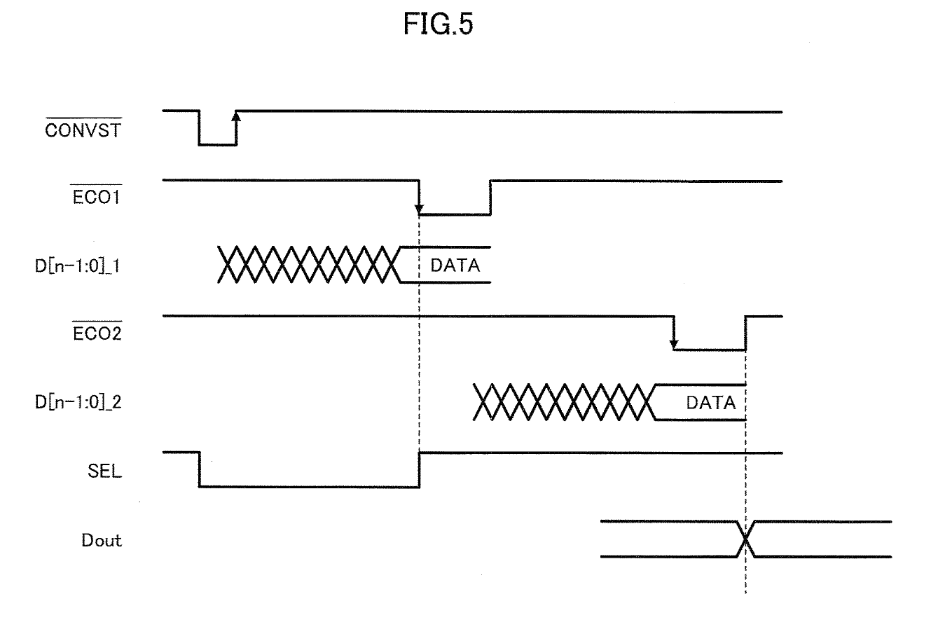

FIG. 5 is a timing chart illustrating the operation of the control circuit 46. A start signal /CONVST applied to the successive approximation register 71 is changed to LOW indicative of assertion. In response, the successive register setting operation of the successive approximation register 71 starts, and, also, the flip-flop 73 is reset to change a selection signal SEL to LOW. The successive approximation register 71 successively determines the values of all the bits stored in an n-bit register in response to the results of comparison supplied from the comparator circuit 44.

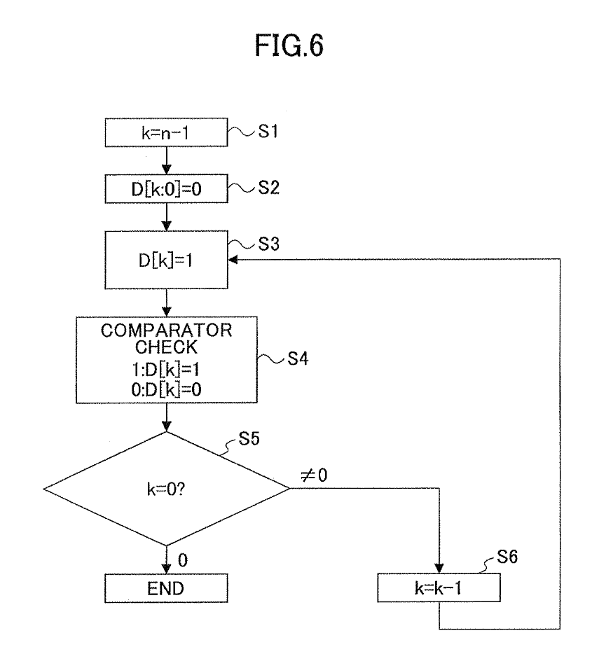

FIG. 6 is a flowchart illustrating the operation sequence of the successive approximation register. The successive approximation register has n-bit values stored therein ranging from the least significant bit D[0] (illustrated as D0 in FIG. 4) to the most significant bit D[n−1] (illustrated as Dn−1 in FIG. 4). Upon the start of operation of the successive approximation register, variable k indicative of a bit position is set to n−1 serving as an initial value in step S1. In step S2, the n-bit values D[k:0] from the bit position 0 to the bit position k are all initialized to zero. In step S3, the bit value D[k] at the bit position k is set to 1. In this state, the control circuit 46 supplies the n-bit values D[k:0] as a digital code to the decoder circuit 47. The decoder circuit 47 causes the switch series 43-2 to select a joint node responsive to the specified digital code, so that the divided voltage Vdiv responsive to the specified digital code is supplied to the comparator circuit 44. The comparator circuit 44 compares the divided voltage Vdiv with the voltage value Vtemp that is temperature dependent, and supplies an output indicative of the result of comparison to the control circuit 46. The control circuit 46 determines the value of D[k] in response to the result of comparison made by the comparator circuit 44 in step S4. Specifically, D[k] is set to 1 if the result of comparison is 1 indicative of Vtemp being greater than Vdiv. Alternatively, D[k] is set to 0 if the result of comparison is 0 indicative of Vtemp being smaller than Vdiv. In step S5, a check is made as to whether k is 0. If k is not 0, the value of k is decremented by 1 in step S6, and, then, the procedure goes back to step S3 to repeat the subsequent steps. Through these steps, a bit value is determined with respect to the next lower bit position. This process is successively repeated from the most significant bit to the least significant bit, thereby determining the n-bit values D[n−1:0]. When this is done, k is equal to 0. With this, the successive register setting operation of the successive approximation register comes to an end.

As illustrated in FIG. 5, when the start signal /CONVST is asserted (LOW) to start the successive register setting operation of the successive approximation register 71, the selection signal SEL that is output from the flip-flop 73 is set to LOW. The register value of the successive approximation register 71 is thus selected by the selector 74 to be supplied to the decoder circuit 47. At this time, the selection signal SEL may be used to control each switch illustrated in FIG. 2. For example, the first switch circuit may be placed in the state in which the inverted input and non-inverted input of the operational amplifier are not swapped. Namely, the switches 33, 34, 35, and 36 may be set to ON, OFF, ON, and OFF, respectively. Further, the second switch circuit may be placed in the state in which the output voltage is output as having a normal phase. Namely, the switches 31 and 32 may be set to ON and OFF, respectively. Further, the third switch circuit may be placed in the state in which the two inputs of the comparator circuit 44 are not swapped. Namely, the switches 51, 52, 53, and 54 may be set to ON, OFF, ON, and OFF, respectively. Further, the fourth switch circuit may be placed in the state in which the output of the comparator circuit 44 is not logically inverted, for example. Namely, the switches 55 and 56 may be set to ON and OFF, respectively.

After the successive register setting operation of the successive approximation register 71 is completed, a process completion signal /EOC (illustrated as /EOC1 in FIG. 4 and FIG. 5) of the successive approximation register 71 is asserted (i.e., changed to LOW). In response to the LOW state of /EOC, the data D[n−1:0] stored in the successive approximation register 71 are stored in the register 82 of the averaging logic circuit 75. In response to the falling edge of /EOC, further, the flip-flop 73 loads “1” to change the selection signal SEL at its output to HIGH (see FIG. 5). Moreover, the LOW state of /EOC triggers the start of the successive register setting operation of the successive approximation register 72. The successive approximation register 72 successively determines the values of all the bits stored in an n-bit register in response to the results of comparison supplied from the comparator circuit 44.

When the successive approximation register 72 performs the successive register setting operation illustrated in FIG. 6, the selection signal SEL output from the flip-flop 73 is HIGH. The register value of the successive approximation register 72 is thus selected by the selector 74 to be supplied to the decoder circuit 47. At this time, the selection signal SEL may be used to control each switch illustrated in FIG. 2. For example, the first switch circuit may be placed in the state in which the inverted input and non-inverted input of the operational amplifier are swapped. Namely, the switches 33, 34, 35, and 36 may be set to OFF, ON, OFF, and ON, respectively. Further, the second switch circuit may be placed in the state in which the output voltage is output as having a reversed phase, for example. Namely, the switches 31 and 32 may be set to OFF and ON, respectively. Further, the third switch circuit may be placed in the state in which the two inputs of the comparator circuit 44 are swapped. Namely, the switches 51, 52, 53, and 54 may be set to OFF, ON, OFF, and ON, respectively. Further, the fourth switch circuit may be placed in the state in which the output of the comparator circuit 44 is logically inverted, for example. Namely, the switches 55 and 56 may be set to OFF and ON, respectively.

After the successive register setting operation of the successive approximation register 72 is completed, a process completion signal /EOC (illustrated as /EOC2 in FIG. 4 and FIG. 5) of the successive approximation register 72 is asserted (i.e., changed to LOW). In response to the LOW state of /EOC, the data D[n−1:0] stored in the successive approximation register 72 are stored in the register 81 of the averaging logic circuit 75.

In the averaging logic circuit 75 illustrated in FIG. 4, the adder circuit 83 obtains the sum of the data stored in the register 81 and the data stored in the register 82. The sum obtained by the adder circuit 83 is stored in the latch circuit 84. The register 85 loads the sum stored in the latch circuit 84 in response to a rising edge of the process completion signal /EOC2 of the successive approximation register 72. As a result, valid output data Dout is obtained in synchronization with the rising edge of /EOC2 as illustrated in FIG. 5. In so doing, the least significant bit of the data stored in the latch circuit 84 may be discarded, and the remaining bits may be stored in the register 85. This arrangement can compute an approximated average value in a simple manner.

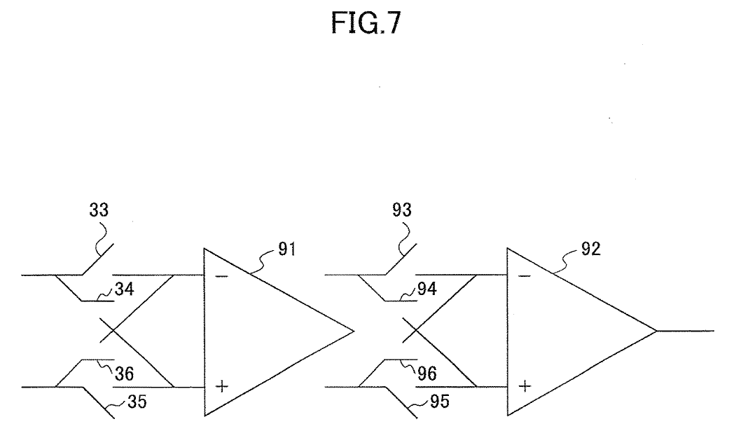

FIG. 7 is a drawing illustrating a variation of the configuration of the second switch circuit provided in the BGR circuit 20. In FIG. 7, the same elements as those of FIG. 2 are referred to by the same numerals, and a description thereof will be omitted. In FIG. 2, one output of the differential amplifier (i.e., transistors 21, 22, 23, 25, and 26) serving as a differential input stage is applied to the single-phase output stage (i.e., transistors 24 and 27), and the second switch circuit is provided between the differential input stage and the single-phase output stage. In such a configuration, the single-phase output stage is selectively coupled via the second switch circuit to either the first output node or second output node of the differential input stage.

On the other hand, the operational amplifier illustrated in FIG. 7 includes a first differential amplifier 91 and a second differential amplifier 92. The second differential amplifier 92 that has a single-phase output is coupled to the differential outputs of the first differential amplifier 91 via the second switch circuit. The first differential amplifier 91 corresponds to the differential amplifier (i.e., transistors 21, 22, 23, 25, and 26) illustrated in FIG. 2. The second differential amplifier 92 replaces the single-phase output stage (i.e., transistors 24 and 27) illustrated in FIG. 2. The second switch circuit includes switches 93 through 96 as illustrated in FIG. 7. The second switch circuit can select either a state in which signals are swapped or a state in which the signals are not swapped on the paths connecting the differential outputs of the first differential amplifier 91 to the differential inputs of the second differential amplifier 92.

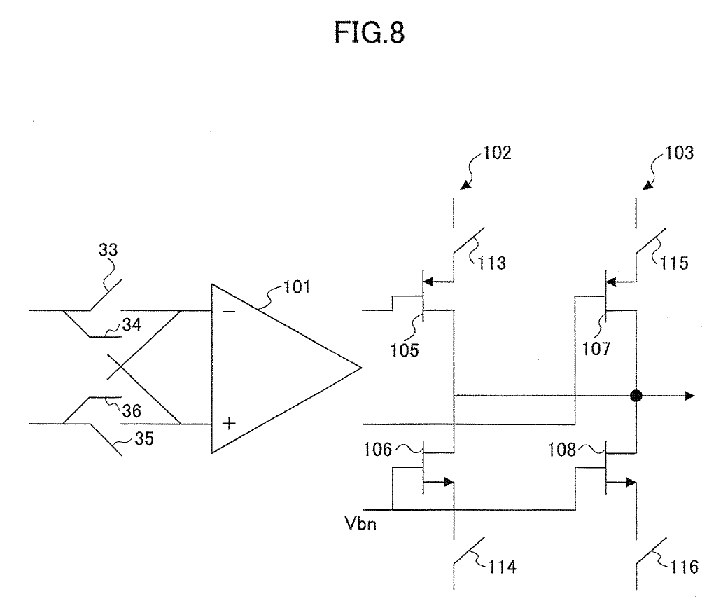

FIG. 8 is a drawing illustrating a further variation of the configuration of the second switch circuit provided in the BGR circuit 20. In FIG. 8, the same elements as those of FIG. 2 are referred to by the same numerals, and a description thereof will be omitted. The operational amplifier illustrated in FIG. 8 includes a differential input stage 101, a first single-phase output stage 102 coupled to a first output node of the differential input stage 101, and a second single-phase output stage 103 coupled to a second output node of the differential input stage 101. The differential input stage 101 corresponds to the differential amplifier (i.e., transistors 21, 22, 23, 25, and 26) illustrated in FIG. 2. The single-phase output stages 102 and 103 replace the single-phase output stage (i.e., transistors 24 and 27) illustrated in FIG. 2. The single-phase output stage 102 includes a series-connected PMOS transistor 105 and NMOS transistor 106 connecting between the power supply voltage and the ground voltage via the second switch circuit. The single-phase output stage 103 includes a series-connected PMOS transistor 107 and NMOS transistor 108 connecting between the power supply voltage and the ground voltage via the second switch circuit. The second switch circuit includes switches 113 through 116 as illustrated in FIG. 8. The second switch circuit can couple one of the single-phase output stages 102 and 103 to the power supply voltage and the ground voltage, so that the output of the coupled one of the single-phase output stages 102 and 103 is selectively activated.

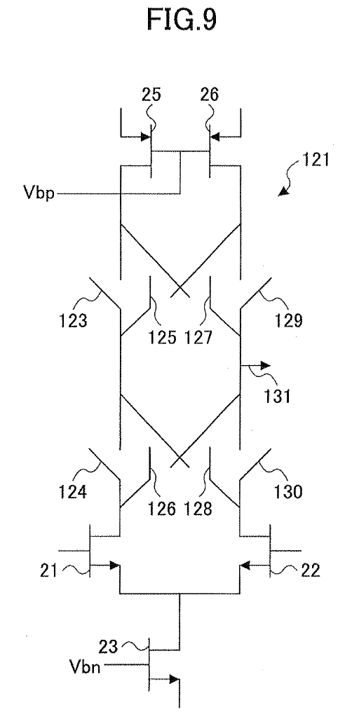

FIG. 9 is a drawing illustrating a further variation of the configuration of the second switch circuit provided in the BGR circuit 20. In FIG. 9, the same elements as those of FIG. 2 are referred to by the same numerals, and a description thereof will be omitted. An operational amplifier illustrated in FIG. 9 is configured such that the second switch circuit is incorporated into a differential input stage 121 including the transistors 21, 22, 23, 25, and 26 illustrated in FIG. 2. An output node 131 of the differential input stage 121 is connected to the gate of the PMOS transistor 27 illustrated in FIG. 2 without a switch circuit intervening therebetween. The second switch circuit includes switches 123 through 130 as illustrated in FIG. 9 to switch the polarities of the output node 131 of the differential input stage 121. Namely, the second switch circuit can switch between a state in which the output node 131 is coupled to a joint point between the PMOS transistor 25 and the NMOS transistor 21 and a state in which the output node 131 is coupled to a joint point between the PMOS transistor 26 and the NMOS transistor 22. Such switching operation can switch the polarities of the output node 131.

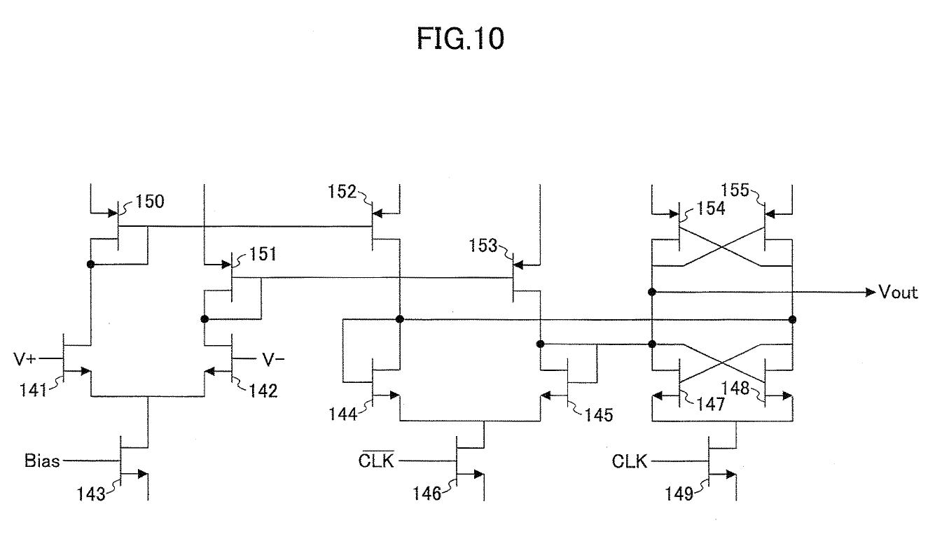

FIG. 10 is a drawing illustrating an example of the configuration of the comparator circuit 44. The comparator circuit 44 includes NMOS transistors 141 through 149 and PMOS transistors 150 through 155. The NMOS transistors 141 through 143 and PMOS transistors 150 and 151 mainly constitute a first stage differential amplifier. The NMOS transistors 144 through 146 and PMOS transistors 152 and 153 mainly constitute a second stage differential amplifier. Further, the NMOS transistors 147 through 149 and the PMOS transistors 154 and 155 constitute a latch circuit of the output stage. The first stage differential amplifier operates all the time based on a bias voltage Bias applied to the gate of the NMOS transistor 143. The second stage differential amplifier operates during the HIGH periods of an inverted clock signal /CLK that is applied to the gate of the NMOS transistor 146. The latch circuit of the output stage operates during the HIGH periods of a clock signal CLK applied to the gate of the NMOS transistor 149. With this arrangement, a signal that is HIGH or LOW depending on a potential difference between input voltages V+ and V− is latched by the output stage latch in response to a rising edge of the clock signal CLK.

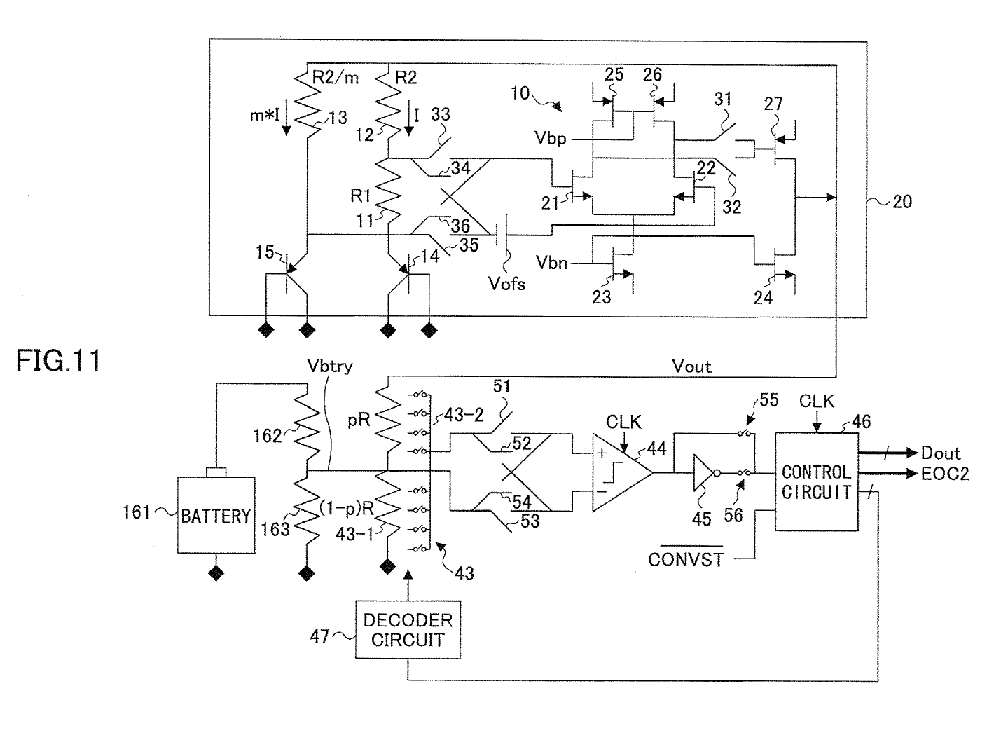

FIG. 11 is a drawing illustrating an example of the system configuration that measures battery voltage by use of an A/D converter. In FIG. 11, the same elements as those of FIG. 1 and FIG. 2 are referred to by the same numerals, and a description thereof will be omitted. The battery voltage measurement circuit illustrated in FIG. 11 applies the voltage generated by a battery 161 to series-connected resistors 162 and 163. A voltage Vbtry appearing at a joint node between the resistor 162 and the resistor 163 is supplied to the comparator circuit 44 as an input analog voltage. The voltage generated by the battery 161 varies depending on the degree of depletion of the battery. The degree of depletion of the battery, i.e., the remaining lifetime of the battery, can be determined by detecting such a voltage level by use of an A/D converter. The comparator circuit 44 compares a voltage obtained by dividing the reference voltage Vout generated by the BGR circuit 20 with the voltage Vbtry that is dependent on the degree of depletion of the battery. The operations of the A/D converter are the same as those in the configuration illustrated in FIG. 2.

According to at least one embodiment, the connections of the switch circuits are set to opposite positions between the case of obtaining the first digital value and the case of obtaining the second digital value, thereby assigning the component of the offset voltage Voft to either a positive direction or a negative direction. The contribution of this offset voltage Voft is alternately assigned in a positive direction and in a negative direction to obtain the respective digital values, which are then averaged to produce a correct A/D conversion value by canceling out the effect of the offset voltage.

Further, the present invention is not limited to these embodiments, but various variations and modifications may be made without departing from the scope of the present invention. For example, the above-described embodiments have been directed to a configuration in which the successive approximation type A/D converter using a resistor series is employed as a circuit for A/D conversion. Alternatively, a successive approximation type A/D converter using a capacitor array may be employed. Alternatively, a successive approximation type A/D converter that uses a main DAC based on a capacitor array and a sub-DAC based on a resistor series may be employed. Further, any A/D converter may be used as long as it utilizes a reference voltage generated by a band-gap-reference circuit affected by an offset voltage. In place of a successive approximation type A/D converter, a flash-type (parallel comparison type) A/D converter may be employed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. An A/D conversion apparatus, comprising:
a reference voltage generating circuit configured to generate a reference voltage; and
an A/D conversion circuit configured to convert an input analog voltage into a digital value based on the reference voltage, wherein the reference voltage generating circuit includes:
a device having a temperature dependency;
an operational amplifier configured to receive as an input voltage thereof a voltage output from the device in response to the reference voltage and to produce as an output voltage thereof the reference voltage;
a first switch circuit configured to switch between a state in which an inverted input and a non-inverted input of the operational amplifier are swapped and a state in which the inverted input and the non-inverted input are not swapped; and
a second switch circuit configured to switch between a state in which the output voltage of the operational amplifier is output as having a normal phase and a state in which the output voltage of the operational amplifier is output as having a reversed phase,
wherein the A/D conversion circuit obtains a first digital value by setting the first switch circuit and the second switch circuit to a first state, and obtains a second digital value by setting the first switch circuit and the second switch circuit to a second state different from the first state, and produces a result of A/D conversion as a value computed from the first digital value and the second digital value.

2. The A/D conversion apparatus as claimed in claim 1, wherein the computed value is an average of the first digital value and the second digital value.

3. The A/D conversion apparatus as claimed in claim 1, wherein the A/D conversion circuit includes:
a potential divider circuit configured to divide the reference voltage according to a digital code to generate a comparison-purpose voltage;
the comparator circuit configured to receive the comparison-purpose voltage and the input analog voltage as two inputs thereof;
a third switch circuit configured to switch between a state in which the two inputs of the comparator circuit are swapped and a state in which the two inputs of the comparator circuit are not swapped;
a fourth switch circuit configured to switch between a state in which a comparator circuit output indicative of a result of comparison performed by the comparator circuit is logically inverted and a state in which the comparator circuit output is not logically inverted; and
a control circuit coupled to the comparator circuit via the fourth switch to produce the digital code,
wherein the third switch circuit and the fourth switch circuit are set to a third state in a case of obtaining the first digital value, and are set to a fourth state different from the third state in a case of obtaining the second digital value.

4. The A/D conversion apparatus as claimed in claim 1, further comprising a device having a temperature dependency and configured to produce a voltage-dependent voltage as the input analog voltage based on the reference voltage, wherein the result of A/D conversion produced by the A/D conversion circuit indicates a measured temperature.

5. The A/D conversion apparatus as claimed in claim 1, further comprising a circuit configured to provide a voltage responsive to a battery voltage as the input analog voltage.

6. The A/D conversion apparatus as claimed in claim 1, wherein the operational amplifier includes:
a differential input stage configured to amplify a difference between the inverted input and the non-inverted input; and
a single-phase output stage selectively coupled via the second switch circuit to either a first output node or second output node of the differential input stage.

7. The A/D conversion apparatus as claimed in claim 1, wherein the operational amplifier includes:
a first differential amplifier configured to amplify a difference between the inverted input and the non-inverted input; and
a second differential amplifier having a single-phase output and coupled via the second switch circuit to differential outputs of the first differential amplifier.

8. The A/D conversion apparatus as claimed in claim 1, wherein the operational amplifier includes:
a differential input stage configured to amplify a difference between the inverted input and the non-inverted input;
a first single-phase output stage coupled to a first output node of the differential input stage; and
a second single-phase output stage coupled to a second output node of the differential input stage,
wherein the second switch circuit is configured to selectively activate an output of the first single-phase output stage or an output of the second single-phase output stage.

9. The A/D conversion apparatus as claimed in claim 1, wherein the operational amplifier includes:
a differential input stage configured to amplify a difference between the inverted input and the non-inverted input; and
a single-phase output stage coupled to an output node of the differential input stage,
wherein the second switch circuit is configured to switch polarities of the output node of the differential input stage.

10. A method of performing A/D conversion in an A/D conversion circuit which generates a reference voltage by use of a reference voltage generating circuit, and converts an input analog voltage into a digital value based on the reference voltage, the reference voltage generating circuit including:
a device having a temperature dependency;
an operational amplifier configured to receive as an input voltage thereof an output voltage of the device responsive to the reference voltage and to produce the reference voltage;
a first switch circuit configured to switch between a state in which an inverted input and non-inverted input of the operational amplifier are swapped and a state in which the inverted input and non-inverted input are not swapped; and
a second switch circuit configured to switch between a state in which an output voltage of the operational amplifier is output as having a normal phase and a state in which the output voltage of the operational amplifier is output as having a reversed phase,
the method comprising the steps of:
obtaining a first digital value by setting the first switch circuit and the second switch circuit to a first state;
obtaining a second digital value by setting the first switch circuit and the second switch circuit to a second stage different from the first state; and
obtaining a result of A/D conversion as a value computed from the first digital value and the second digital value.
